(19) United States
(12) Patent Application Publication
(10) Pub. No.: US 2008/0311715 A1
(43) Pub. Date: Dec. 18, 2008

(54) Method for forming semiconductor device

(75) Inventors: Po-Kang Hu, Tainan City (TW); Cheng-Che Lee, Taichung County (TW); Ta-Wei Tung, Taichung County (TW); Meng-Cheng Chen, Taichung City (TW)

Correspondence Address: BIRCH STEWART KOLASCH & BIRCH, PO BOX 747, FALLS CHURCH, VA, 22040-0747, US

(73) Assignee: ProMOS Technologies Inc.

(21) Appl. No.: 12/068,617

(22) Filed: Feb. 8, 2008

(30) Foreign Application Priority Data
Jun. 12, 2007 (TW) 96121156

(51) Int. Cl. H01L 21/8236

(52) U.S. Cl. 438/278; 257/E21.631

(57) ABSTRACT

A method for forming a semiconductor device is disclosed. A substrate comprising trenches are provided. Dopants are doped into a region of the substrate neighboring a sidewall of the trenches by using an isotropic doping method. A gate dielectric layer is formed on the sidewall of the substrate. A gate electrode is formed in the trenches, wherein the gate electrode protrudes a surface of the substrate.

### BACKGROUND OF THE INVENTION

1. Field of the Invention

The invention relates to a method for forming a semiconductor device, and in more particularly to a method for forming a memory device.

2. Description of the Related Art

A metal oxide semiconductor field effect transistor (MOSFET) is a transistor utilizing VLSI technology comprising a gate, an oxide layer and a semiconductor layer on a semiconductor substrate. A MOSFET further comprises a source region and a drain region with reverse doping type from the substrate on opposite sides of the gate. In general, the gate is polycide, comprising both polysilicon and metal, and the oxide layer is formed by thermal oxidation. Further, spacers comprising silicon nitride are formed on opposite sides of the gate.

As development of MOSFET advances, size and channel lengths are continuously being reduced. When channel length decreases to below 100 nm, short channel effect occurs; specifically, activation and deactivation of the channel controlled by the gate is hindered by source and drain interference. Thus, resulting in a technological barrier in further size and channel length reduction of a MOSFET. Currently, non-planar gate structures, such as recess channel array transistor (RCAT) and sphere shaped recess channel array transistor (SSRCAT) have been developed to combat short channel effect in efforts to further reduce MOSFET size and channel lengths to below 100 nm.

FIGS. 1A and 1B illustrate a conventional implanting process, adjusting threshold voltage of a step gate transistor. First, referring to FIG. 1A, a substrate 102 is provided and then treated with channel implant 103 to form a channel doping region 104. Next, referring to FIG. 1B, surface of the substrate 102 is processed to form a step structure. A gate dielectric layer 106 and a gate electrode 108 are formed on the substrate 102. The substrate 102 is doped to form a source region 120 and a drain region 122. As shown in FIG. 1B, dopants of channel implant cannot diffuse uniformly into the channel region. As such, resulting in an un-uniformed channel doped region.

Channel doping of a recess channel array transistor (RCAT) or a sphere shaped recess channel array transistor (SSRCAT) is accomplished by forming a trench in a substrate and implanting dopants into the trench to form a channel doping region. The channel doping technology of RCAT or SSRCAT, however, also cannot uniformly diffuse dopants into the channel region.

### BRIEF SUMMARY OF INVENTION

Given the technological barriers described above, the purpose of the invention is to provide a method for fabricating a non-planar gate transistor, which is able to uniformly diffuse dopants into a channel region. A detailed description is given in the following embodiments with reference to the accompanying drawings. The above mentioned barriers and other related problems are generally mitigated or circumvented and technical advantages are generally achieved by the invention.

The invention provides a method for forming a semiconductor device. A substrate comprising a trench is provided. Dopants are doped into a region of the substrate neighboring a sidewall of the trench by using an isotropic doping method. A gate dielectric layer is formed on the sidewall of the substrate. A gate electrode is formed in the trench, wherein the gate electrode protrudes a surface of the substrate.

The invention provides a method for forming a semiconductor device. A substrate comprising a trench is provided. A doping layer is formed on a sidewall of the trench. A barrier layer is formed, at least covering the doping layer. The substrate is heated to diffuse dopants of the doping layer into a region of the substrate neighboring the sidewall of the trench. A gate dielectric layer is formed on the sidewall of the substrate. A gate electrode is formed in the trench, wherein the gate electrode protrudes a surface of the substrate.

The invention provides a method for forming a semiconductor device. A substrate is provided, comprising a trench and a mask layer above the trench. The substrate is placed in a reacting chamber, a doping gas is introduced into the chamber, and the substrate is heated to diffuse dopants to a region of the substrate neighboring a sidewall of the trench. A gate dielectric layer is formed on the sidewall of the trench. A gate electrode is formed in the trench, wherein the gate electrode protrudes a surface of the substrate.

### BRIEF DESCRIPTION OF DRAWINGS

The invention can be more fully understood by reading the subsequent detailed description and examples with references made to the accompanying drawings, wherein:

FIGS. 1A and 1B illustrate a conventional implanting process for adjusting threshold voltage of a step gate transistor.

FIGS. 2A˜2I illustrate a method for forming a non-planar gate transistor of an embodiment of the invention.

FIGS. 3A˜3F illustrate a method for forming a non-planar gate transistor of another embodiment of the invention.

FIGS. 4A˜4D illustrate a method for forming a non-planar gate transistor of a further embodiment of the invention.

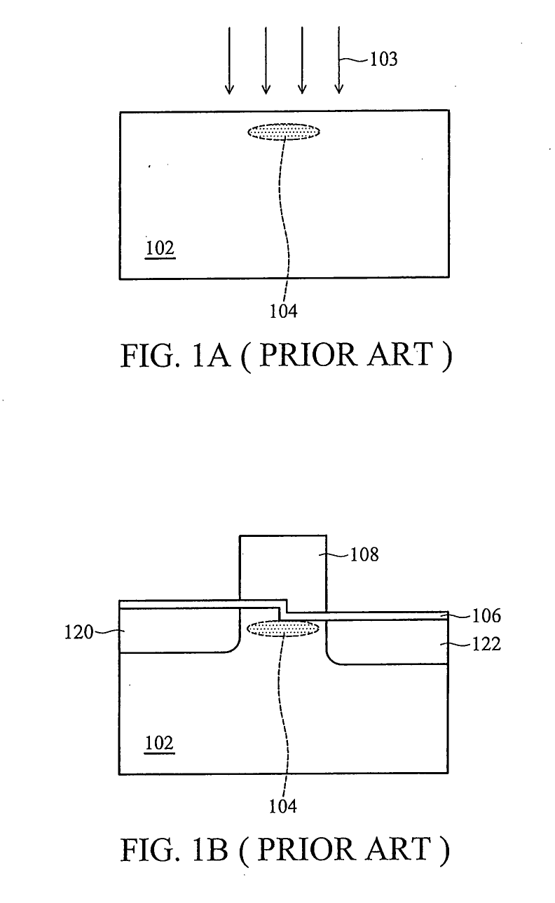

### DETAILED DESCRIPTION OF INVENTION

The following description is the best-contemplated mode of carrying out the invention. This description is made for the purpose of illustrating the general principles of the invention and should not be taken in a limiting sense. The scope of the invention is best determined by reference to the appended claims. Embodiments of the invention are described with reference to the drawings and like elements are referred to by like reference numerals.

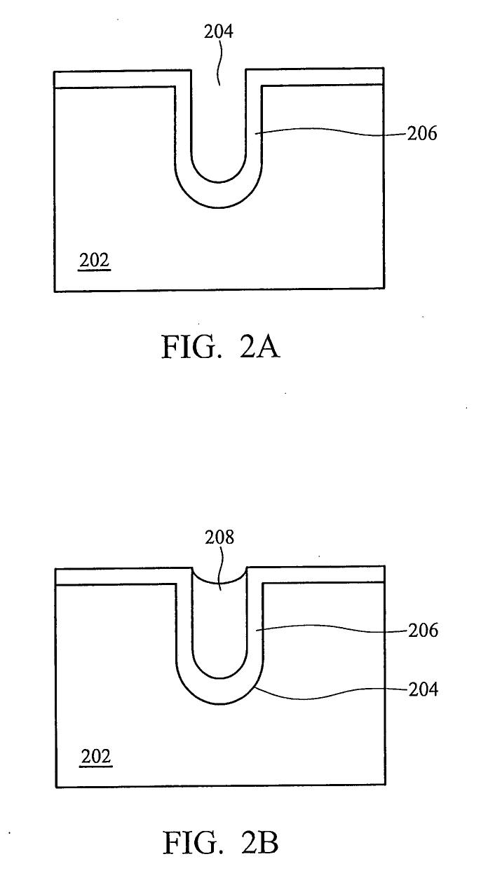

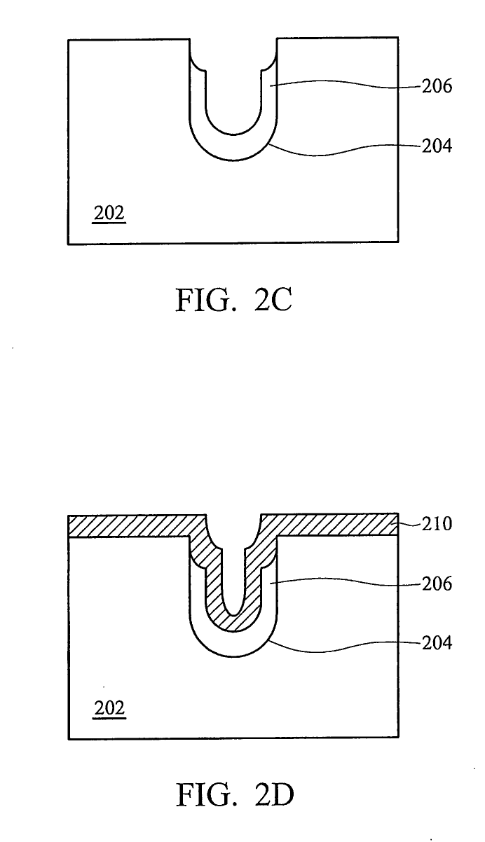

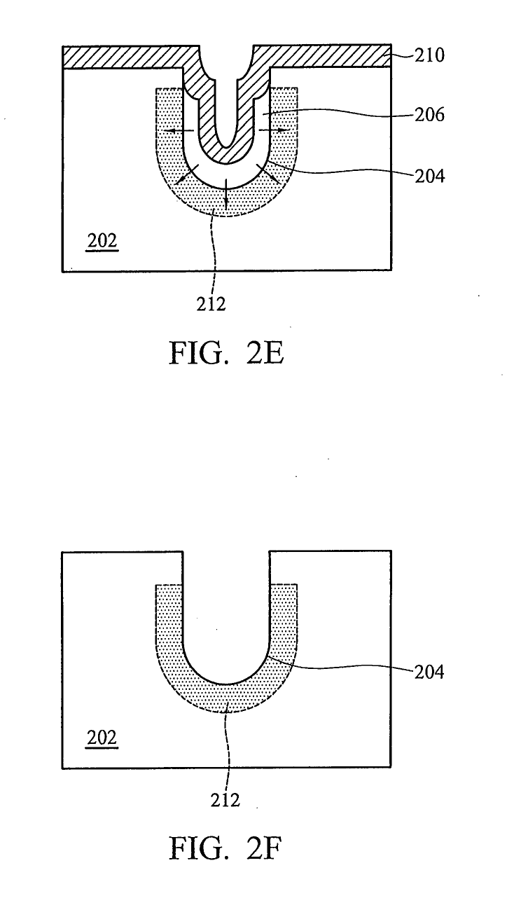

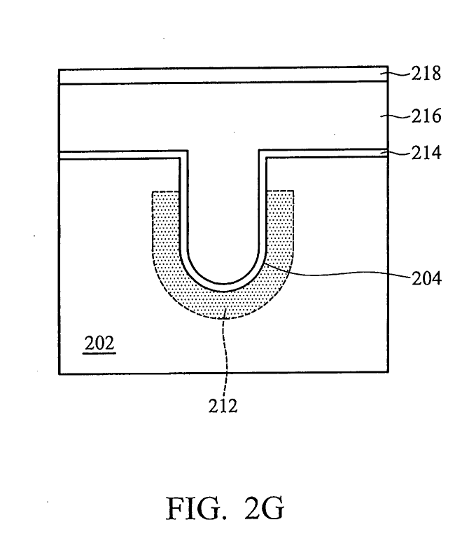

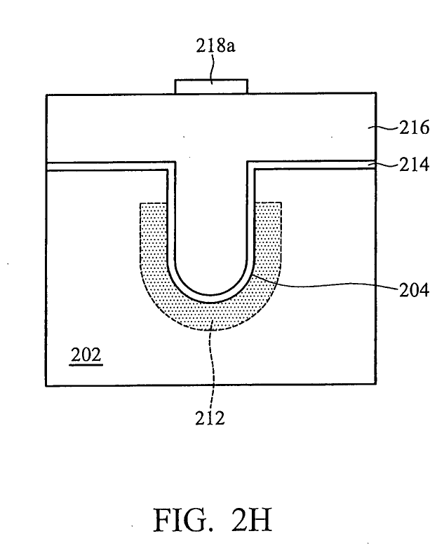

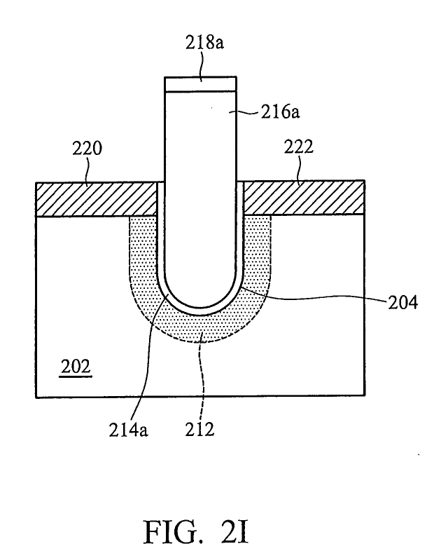

FIGS. 2A˜2I illustrate a method for forming a non-planar gate transistor of an embodiment of the invention. Referring to FIG. 2A, a substrate 202 is provided, and then a trench 204 is formed therein by photolithography and etching process. A doping layer 206 is conformally formed on the substrate 202 and in the trench 204 by low pressure chemical vapor deposition (LPCVD) or sub-atmospheric chemical vapor deposition (SACVD). In an embodiment of the invention when the transistor is NMOS, the doping layer 206 is doped with p type dopants, such as boron silicon glass (BSG). In another embodiment of the invention when the transistor is PMOS, the doping layer 206 is doped with n type dopants, such as phosphorus silicon glass (PSG) or arsenic silicon glass (ASG).

Referring to FIG. 2B, a photoresist (not shown) is formed on the doping layer 206 and in the trench 204. Next, a portion of the photoresist beyond the trench 204 is removed (e.g. by plasma stripper), and another portion remains in the trench 204. In this embodiment, the portion of the photoresist in the trench is referred as a mask layer 208. Note that the mask layer 208 is not limited to a photoresist in the invention. The mask layer 208 can comprise other materials, such as nitride or other macromolecule.

Referring to FIG. 2C, using the mask layer 208 as a mask and removing a portion of the doping layer 206 in the trench 204 by etching process, and another portion of the doping layer 206 remains in the trench 204. In the embodiment of the invention, the etching step is executed by dipping buffer oxide etch (BOE) solution. Thereafter, the mask layer 208 formed of photoresist is removed, by, for example, plasma stripper.

Next, referring to FIG. 2D, a barrier layer 210 is formed on the substrate 202 by, for example, plasma enhanced chemical vapor deposition (PECVD), covering the doping layer 206 in the trench 204 to limit diffusion of dopants from the doping layer 206 during a subsequent thermal process. In the embodiment of the invention, the barrier layer 210 is tetra-ethyl-ortho-silicate (TEOS). Thereafter, referring to FIG. 2E, a thermal process is conducted to diffuse dopants in the doping layer 206 into a region of the substrate 202 (the channel doping region 212 as shown in the figure) neighboring sidewalls of the trench 204. Note that temperature of the thermal process is dependant upon process window and product specifications, and top of the channel doping region 212 preferably does not exceed the bottom of the source and drain regions formed in a subsequent step. In a preferred embodiment of the invention, temperature of the thermal process is about 650° C.˜850° C. Unlike prior technology, in this embodiment dopants can be uniformly disposed in the region (channel region of the non-planar gate transistor) neighboring sidewalls of the trench 204 in the substrate 202.

Referring to FIG. 2F, the doping layer 206 and the barrier layer 210 are removed. When the doping layer 206 is boron silicon glass (BSG), phosphorus silicon glass (PSG) or arsenic silicon glass (ASG), and the barrier layer 210 is TEOS, they can be simultaneously removed by immersion with BOE. Referring to FIG. 2G, a gate dielectric film 214, such as silicon oxide, is formed in the trench 204 and on the substrate 202. A gate electrode layer 216 is formed on the gate dielectric film 214 and filled into the trench 204, and then planarized by, for example, chemical mechanical polishing CMP. A hard mask layer 218, such as silicon nitride, is formed on the gate electrode layer 216. The steps of forming the gate dielectric film 214 and the gate electrode layer 216 are well known in the art, and thus are not illustrated in detail herein.

Referring to FIG. 2H, the hard mask layer 218 is defined by photolithography and etching process to form a patterned hard mask layer 218a. Referring to FIG. 21, anisotropic etching is conducted using the patterned hard mask layer 218a as a mask to pattern the gate electrode layer 216 and the gate dielectric film 214, constituting a structure comprising a gate dielectric layer 214a on sidewalls of the trench 204, and a gate electrode 216a in the trench 204 and protruding the substrate 202 surface. Next, an ion implanting process is conducted to form a source region 220 and a drain region 222 in the substrate 202 neighboring opposite sides of the gate electrode 216a.

In the embodiment, since the channel doping region 212 of the non-planar gate transistor is doped by diffusion of the doping layer 206 on the trench 204 sidewalls into the substrate 202, dopants in the channel region are more uniform to eliminate short channel effect. Further, due to less short channel effect, the transistor formed by the method of the embodiment has less current leakage, increasing retention time of a dynamic random access memory (DRAM).

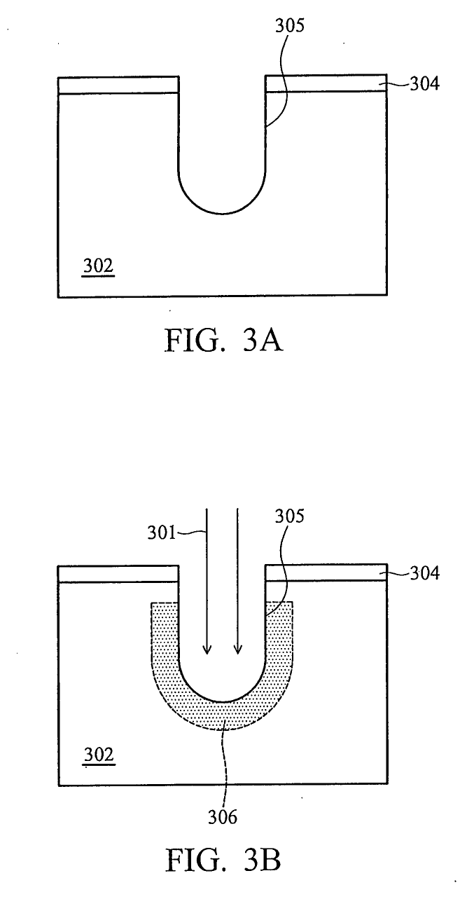

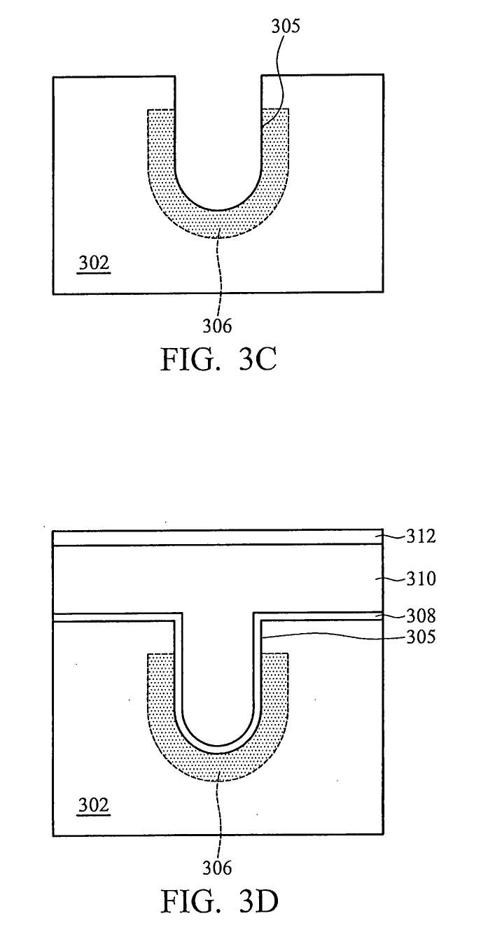

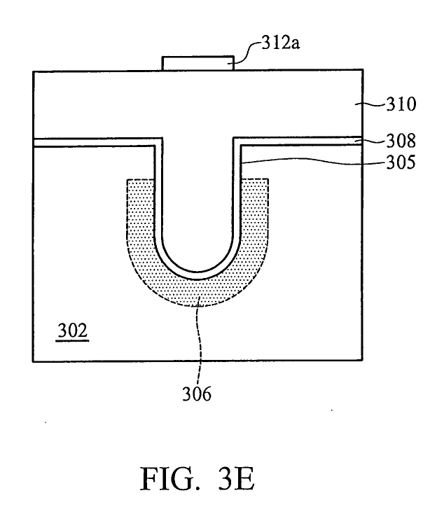

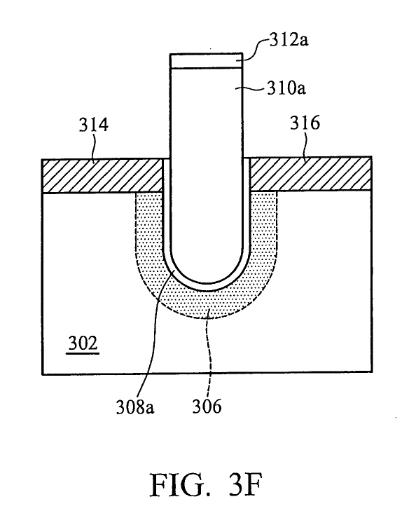

FIGS. 3A˜3F illustrate a method for forming a non-planar gate transistor of another embodiment of the invention. Referring to FIG. 3A, a substrate 302 is provided, and a mask layer 304, such as silicon nitride, is formed thereon. The substrate 302 is etched using the mask layer 304 as a mask by photolithography to form a trench 305 therein. Next, referring to FIG. 3B, the substrate 302 is placed in a reacting chamber, and a doping gas 301 is introduced. Dopants of the doping gas 301 are diffused into a region (as the channel doping region 306 in FIG. 3B) of the substrate 302 neighboring the trench 305 sidewalls by heating the device. When the device is NMOS, the doping gas 301 preferably is a boron containing gas, such as BF₂. When the device is PMOS, the doping gas 301 preferably is an arsenic or phosphorous containing gas, such as PH₃ or AsH₃. Next, referring to FIG. 3C, the mask layer 304 overlying the substrate 302 is removed.

Referring to FIG. 3D, a gate dielectric film 308, such as silicon oxide, is formed in the trench 305 and on the substrate 302. A gate electrode layer 310 is formed on the gate dielectric film 308 and filled into the trench 305, and then planarized by, for example, chemical mechanical polishing CMP to have a planar surface. A hard mask layer 312, such as silicon nitride, is formed on the gate electrode layer 310. In an embodiment of the invention, the gate dielectric film 308 can be in-situ formed at the same reacting chamber for diffusing dopants of the doping gas into a region neighboring the trench 305 sidewalls. In another embodiment of the invention, the gate dielectric film 308 and the gate electrode layer 310 can be in-situ formed at the same reacting chamber for diffusing dopants of the doping gas into the region neighboring the trench 305 sidewalls

Referring to FIG. 3E, the hard mask layer 312 is patterned by photolithography and etching process to form a patterned hard mask layer 312a. Next, referring to FIG. 3F, anisotropic etching is conducted using the patterned hard mask layer 312a as a mask to pattern the gate electrode layer 310 and the gate dielectric film 308, constituting a structure comprising a gate dielectric layer 308a on sidewalls of the trench 305, and a gate electrode 310a in the trench 305 and protruding the substrate 302 surface. Next, an ion implanting process is conducted to form a source region 314 and a drain region 316 in the substrate 302 neighboring opposite sides of the gate electrode 310a.

Since the channel region of the non-planar gate transistor of the embodiment is doped by thermal diffusion, dopants in the channel region are also uniformly disposed, thus effectively eliminating short channel effect.

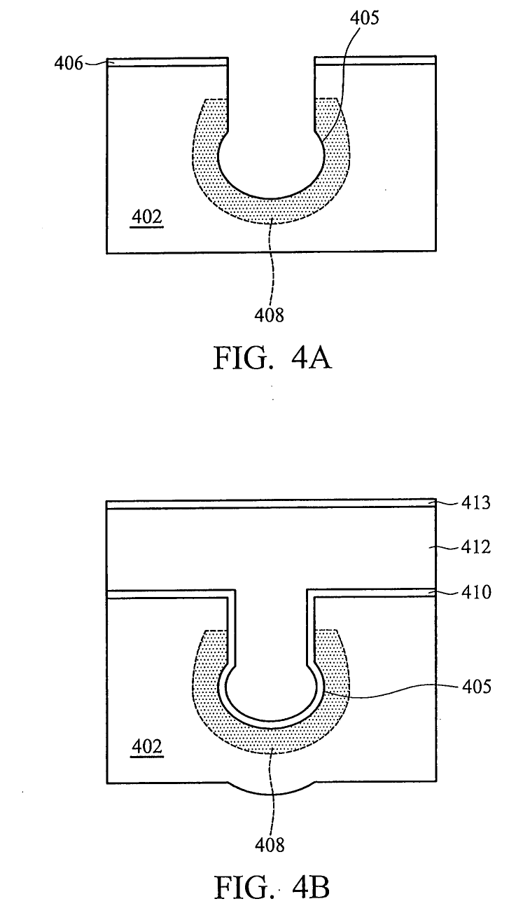

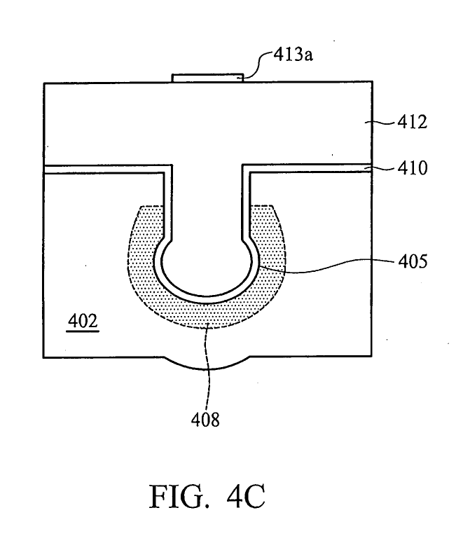

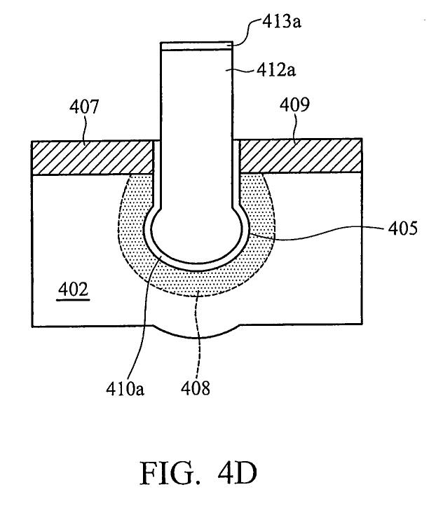

Note that the trench of the invention is not limited to a column shape, and can be other shapes. The doping method provided by the invention can also uniformly diffuse dopants into the channel region for non-planar gate transistors with other shaped trenches. For example, referring to FIG. 4A, the embodiment uses a bottle-shaped trench 405 with a wider lower portion and narrower top portion in a substrate 402. Doping of the channel region can be achieved by like methods described in previous embodiments. For example, the substrate 402 is placed in a chamber, which is then inlet with doping gas and heated to thermally diffuse dopants into a region of the substrate 402 neighboring sidewalls of the bottle-shaped trench 405 using a mask layer 406 as a mask. In another example, a doping layer (not shown) is formed on sidewalls of the bottle-shaped trench 405, and then heated to diffuse dopants into a region of the substrate 402 neighboring sidewalls of the bottle-shaped trench 405, thus forming a channel doping region 408. Thereafter, the mask layer 406 is removed.

Referring to FIG. 4B, a gate dielectric film 410, such as silicon oxide, is formed in the bottle-shaped trench 405 and on the substrate 402. A gate electrode layer 412 is formed on the gate dielectric film 410 and filled into the bottle-shaped trench 405, and then planarized by, for example, by chemical mechanical polishing CMP. A hard mask layer 413, such as silicon nitride, is formed on the gate electrode layer 412. A hard mask layer 413, such as silicon nitride, is formed on the gate electrode layer 412. Referring to FIG. 4C, the hard mask layer 413 is patterned by photolithography and etching process to form a patterned hard mask layer 413a. Thereafter, referring to FIG. 4D, the gate electrode layer 412 and the gate dielectric film 410 are patterned by anisotropic etching using the patterned hard mask layer 413a as a mask to constitute a structure comprising a gate dielectric layer 410a on the sidewalls of the bottle-shaped trench 405, and a gate electrode 412a in the bottle-shaped trench 405 and protruding the substrate 402 surface. Next, an ion implanting process is conducted to form a source region 407 and a drain region 409 in the substrate 402 neighboring opposite sides of the gate electrode 412a.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for forming a semiconductor device, comprising:
providing a substrate having trenches;
doping dopants into a region of the substrate neighboring a sidewall of the trenches by using an isotropic doping method;
forming a gate dielectric layer on the sidewall of the substrate; and
forming a gate electrode in the trenches, wherein the gate electrode protrudes a surface of the substrate.

2. The method for forming a semiconductor device as claimed in claim 1, wherein the isotropic doping method comprises:
forming a doping layer on the sidewall of the trenches; and
heating the doping layer to diffuse the dopants into the region of the substrate neighboring the sidewall of the trenches.

3. The method for forming a semiconductor device as claimed in claim 1, wherein the isotropic doping method comprises:
placing the substrate in an environment comprising a doping gas with the dopants; and
heating the substrate to diffuse the dopants into the region of the substrate neighboring the sidewall of the trenches.

4. The method for forming a semiconductor device as claimed in claim 1, further comprising a step of forming a source region and a drain region in the substrate neighboring opposite sides of the gate electrode.

5. The method for forming a semiconductor device as claimed in claim 1, wherein the dopants diffuse into a channel region of the semiconductor device by the isotropic doping method to constitute a channel doping region.

6. The method for forming a semiconductor device as claimed in claim 5, wherein the top of the channel region is lower than the bottom of the source and the drain regions.

7. The method for forming a semiconductor device as claimed in claim 1, wherein the dopants are uniformly diffusing into the region of the substrate neighboring the sidewall of the trenches.

8. The method for forming a semiconductor device as claimed in claim 1, wherein the trenches are bottle-shaped trenches with a narrower top portion and a wider lower portion.

9. A method for forming a semiconductor device, comprising:
providing a substrate having trenches;
forming a doping layer on a sidewall of the trenches;
forming a barrier layer and at least covering the doping layer;
heating the substrate to diffuse dopants in the doping layer to a region of the substrate neighboring the sidewall of the trenches;
forming a gate dielectric layer on the sidewall of the substrate; and
forming a gate electrode in the trenches, wherein the gate electrode protrudes a surface of the substrate.

10. The method for forming a semiconductor device as claimed in claim 9, wherein the semiconductor device is NMOS, and the dopants in the doping layer comprise boron silicon glass (BSG).

11. The method for forming a semiconductor device as claimed in claim 9, wherein the semiconductor device is PMOS, and the dopants in the doping layer comprise phosphorus silicon glass (PSG) or arsenic silicon glass (ASG).

12. The method for forming a semiconductor device as claimed in claim 9, wherein the step of forming the doping layer on the sidewall of the trenches comprise:
blanketly forming a mask layer on the doping layer and filling into the trenches;
removing a portion of the mask layer in the trenches; and
removing a portion of the doping layer in the trenches by etching process and using the mask layer as a mask.

13. The method for forming a semiconductor device as claimed in claim 12, wherein the mask layer is photoresist.

14. The method for forming a semiconductor device as claimed in claim 9, wherein the barrier layer comprises tetra-ethyl-ortho-silicate (TEOS).

15. The method for forming a semiconductor device as claimed in claim 9, wherein the dopants of the doping layer are diffused uniformly into to the region of the substrate neighboring the sidewall of the trenches.

16. The method for forming a semiconductor device as claimed in claim 9, wherein the trenches are bottle-shaped trenches with a narrower top portion and a wider lower portion.

17. A method for forming a semiconductor device, comprising:
providing a substrate, comprising trenches and a mask layer beyond the trenches;
placing the substrate into a reacting chamber, introducing a doping gas into the reaction chamber, and heating the substrate to diffuse dopants into a region of the substrate neighboring a sidewall of the trenches;
forming a gate dielectric layer on the sidewall of the trenches; and
forming a gate electrode in the trenches, wherein the gate electrode protrudes a surface of the substrate.

18. The method for forming a semiconductor device as claimed in claim 17, wherein the semiconductor device is NMOS, and the doping gas comprises boron.

19. The method for forming a semiconductor device as claimed in claim 17, wherein a gate dielectric film and a gate electrode layer are in-situ formed during the step of diffusing the dopants into the region of the substrate, and the gate dielectric film and the gate electrode layer are subsequently patterned to constitute the gate dielectric layer and the gate electrode.

20. The method for forming a semiconductor device as claimed in claim 17, wherein the semiconductor device is PMOS, and the doping gas comprises phosphorus or arsenic.

21. The method for forming a semiconductor device as claimed in claim 17, wherein the trenches are bottle-shaped trenches with a narrower top portion and a wider lower portion.
